(19) United States
(12) Patent Application Publication
(10) Pub. No.: US 2007/0075880 A1
(43) Pub. Date: Apr. 5, 2007

(54) Coding circuit and coding apparatus

(75) Inventor: Kenji Uchida, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/527,546

(22) Filed: Sep. 27, 2006

(30) Foreign Application Priority Data
Sep. 30, 2005 (JP) 2005-286987

(51) Int. Cl. H03M 7/34

(52) U.S. Cl. 341/51

(57) ABSTRACT

Disclosed is a coding circuit including: a data delay unit to delay a second signal as a third signal, the second signal comprising one of two data produced by splitting a data for cording, a first signal comprising the other data; a first arithmetic unit to calculate a logic product of the first signal and a first clock signal as a fourth signal; a second arithmetic unit to calculate the logic product of the third signal and an inverted signal of the first clock signal as a fifth signal; a first holding signal inversion unit to invert an output signal as a sixth signal according to the fourth signal; a second holding signal inversion unit to invert an output signal as a seventh signal according to the fifth signal; and an exclusive OR operation unit to calculate an exclusive OR of the sixth signal and the seventh signal.

### BACKGROUND OF THE INVENTION

1. Field of the Invention

This invention relates to a coding circuit and a coding apparatus suitably used for processing such modulation scheme as the differential phase shift keying (DPSK).

2. Description of Related Art

In recent years, the bit rate of optical communication has increased to such an extent that an optical communication system for transmitting the signal of as fast as 40 Gb/s is now under development. In an optical communication system, various coding techniques are used for transmitting the input data from the transmitter to the receiver. The DPSK (differential phase shift keying) communication scheme is known as one of such coding techniques.

The DPSK communication scheme is realized by phase modulation of the light. The phase modulation of the light is carried out by changing the phase of the light in accordance with the data (row of 1s and 0s) to be transmitted. With reference to FIGS. 4 and 5, the phase modulation of the light is explained below. Also, with reference to FIGS. 6 to 8, the conventional coding circuit is explained.

FIG. 4 shows the phase space of the light. In FIG. 4, the ordinate represents the imaginary part (Im) and the abscissa represents the real part (Re). In this case, the light is expressed by Equation (1) indicating a sinusoidal wave.

Amplitude of light sinusoidal wave =Asin(ωt +φ) . . . (1)

In Equation (1), A is the maximum value of the amplitude of the light, ω the angular frequency, t the time and φ the phase. In Equation (1), the phase φ assumes the value of 0 (rad) or π (rad) on the real part shown in FIG. 4.

When a modulation rule is such that the phase is held as it is in the case where the data to be transmitted is 0, and the phase undergoes a change (from 0 to π or from π to 0) in the case where the data to be transmitted is 1, the modulation rule satisfies the DPSK communication scheme. Specifically, in the DPSK communication scheme, the data to be transmitted is coded by the phase change of the light, and therefore, at the receiving end, the data can be discriminated from the phase change of the light received (Assuming that the aforementioned modulation rule is applicable, the data is 1 when the phase changes and the data is 0 when the phase remains unchanged at the receiving end).

FIG. 5 shows a configuration for phase modulation by a LiNbO₃ modulator (LN modulator). An LN modulator 19 is a LiNbO₃ modulator for conducting the phase modulation of the light. An optical input S22 is the light input to the LN modulator 19, and an optical output S23 is the light output from the LN modulator 19. A control signal S7 is applied to the LN modulator 19 and is standardized signal of 0 or 1.

The operation of the LN modulator 19 shown in FIG. 5 is explained. The LN modulator 19 is included in the transmitter of the DPSK communication system. The DPSK communication system comprises a transmitter, a receiver and a transmission medium between the transmitter and the receiver (not shown). An optical carrier signal (optical input S22) is generated from a light source such as a laser included in the transmitter and input to the LN modulator 19. In the process, the optical input S22 is the light whose phase is constantly 0 (rad). Then, the control signal S7 is applied to the LN modulator 19. When the control signal S7 is 0, the optical output S23 of 0 (rad) is output, and when the control signal S7 is 1, the optical output S23 of π (rad) is output. The optical output S23 is converted into a form suited for optical transmission medium such as an optical fiber through an optical amplifier. The light transmitted through the transmission medium is received by the receiver.

In this DPSK communication system, the light of the optical input S22 is phase modulated according to the control signal S7. By acquiring the control signal S7 to meet the DPSK modulation rule (i.e. the phase is held as it is for data 0, and the phase is changed by π for data 1), therefore, the DPSK communication scheme can be realized.

FIG. 6 shows the conventional coding system to acquire the control signal S7. The conventional coding circuit 22 comprises an AND circuit 20 and a T-FF (T flip-flop) 21.

In the following description, the bit rate after coding is assumed to be 40 Gb/s. An input signal S24 is NRZ (non return to zero) original signal (40 Gb/s), and an input signal S25 is a clock signal (40 GHz). The AND circuit 20 is an arithmetic circuit to produce a logic product, and the T flip-flop 21 is a 1-bit flip-flop whose output is inverted every time the clock signal is applied thereto. The coding circuit 22 is equivalent to a circuit for outputting the exclusive OR of the input and output signals based on the clock signal (see, for example, JP 2002-64574A).

Next, with reference to FIGS. 6 and 7, the operation of the conventional coding circuit 22 shown in FIG. 6 is explained. In FIG. 6, the input signals S24, S25 are input to the AND circuit 20. The AND circuit 20 calculates the logic product of the input signals S24 and S25 and produces an output signal S26. The output signal S26 is input to the T flip-flop 21 from which the control signal S7 is output.

FIG. 7 shows an example of a timing chart for the circuit of FIG. 6. In FIG. 7, S24, S25, S26 and S7 designate the input signals S24, S25, the output signal S26 and the control signal S7, respectively, shown in FIG. 6. The bit period of the signal S24 is 25 ps. In FIG. 7, S24 designates a NRZ signal, and S25 a clock signal. The signal S26 is an output of the AND circuit 20 shown in FIG. 6, and constitutes a RZ (return to zero) signal which raises one up-edge every time the NRZ signal generates 1. Assuming that the T flip-flop 21 shown in FIG. 6 is toggled by the up-edge, the control signal S7 shown in FIG. 7 is produced.

FIG. 8 shows a configuration of a coding apparatus 200 including the coding circuit 22 shown in FIG. 6. The coding apparatus 200 shown in FIG. 8 comprises 2-to-1 multiplexers 23, 24, 25 and the coding circuit 22.

The input signals S1, S2, S3 and S4 have the bit rate of 10 Gb/s. The 2-to-1 multiplexers 23, 24 and 25 convert the input signal to a signal of a double bit rate. The coding circuit 22 is equivalent to the circuit shown in FIG. 6.

Next, the configuration shown in FIG. 8 is explained. The input signals S1, S2, S3 and S4 are input in that order from respective ports as a 10 Gb/s signal to be converted into a serial 40 Gb/s signal. They are generated at the same timing. These signals in input signal pairs of S1 and S2, and S3 and S4 are input to the 2-to-1 multiplexers 23 and 24, respectively, thereby to produce output signals S5 and S6 of 20 Gb/s. The output signals S5 and S6 are further input to the 2-to-1 multiplexer 25 so that an output signal S24 of 40 Gb/s is produced. The output signal S24 is equivalent to the input signal S24 in FIG. 6, and a control signal S7 is produced by the operation of the coding circuit 22 shown in FIG. 6.

In the earlier development described above, in the case where the signal of 40 Gb/s is transmitted by the DPSK communication scheme, the input signal S24 constitutes the NRZ signal of 40 Gb/s, and the input signal S25 the clock signal of 40 GHz. It is difficult to configure an AND circuit 20 for processing such a high-speed signal. It is also difficult in terms of the circuit operation speed to configure the T flip-flop 21 being toggled according to the output signal S26.

### SUMMARY OF THE INVENTION

It is an object of the present invention to provide a coding circuit and a cording apparatus for an optical communication system, in which the precoding of a signal having high bit rate can be carried out stably.

In order to attain the above object, according to a first aspect of the invention, a coding circuit comprises: a data delay unit to delay a period of a second signal by one half bit and to output the delayed second signal as a third signal, the second signal comprising one of two data produced by splitting a data for cording parallely and alternately, a first signal comprising the other data; a first arithmetic unit to calculate a logic product of the first signal and a first clock signal having the same frequency as a bit rate of the first signal and to output a resultant signal as a fourth signal; a second arithmetic unit to calculate the logic product of the third signal and an inverted signal of the first clock signal and to output a resultant signal as a fifth signal; a first holding signal inversion unit to invert the logic value of a data to be output and to output a resultant signal as a sixth signal every time a rising edge of the fourth signal is detected; a second holding signal inversion unit to invert the logic value of a data to be output and to output a resultant signal as a seventh signal every time the rising edge of the fifth signal is detected; and an exclusive OR operation unit to calculate an exclusive OR of the sixth signal and the seventh signal and to output a resultant signal as an eighth signal.

As a result, in a coding circuit of an optical communication system, first and second signals having a processable speed are coded and a high-speed eighth signal can be output, thereby making possible a stable signal precoding at high bit rate.

Preferably, the coding circuit further comprises: a first synchronizing unit to synchronize the first signal with the second signal in synchronization with an input of the first clock signal.

Preferably, the coding circuit further comprises: a first delay unit to delay the first clock signal by a predetermined period and to output a delayed signal as a second clock signal having the same frequency as the first clock signal, wherein the first arithmetic unit calculates a logic product of the first signal and the second clock signal, and the second arithmetic unit calculates a logic product of the third signal and an inverted signal of the second clock signal.

As a result, the circuit operation is made possible with the first and second signals in synchronism with each other.

Preferably, a coding circuit further comprises: a frequency multiplication unit to output a third clock signal having a frequency twice as high as the second clock signal; and a pulse width adjusting unit to adjust a pulse width of the eighth signal by synchronizing the eighth signal with the third clock signal.

Preferably, a coding circuit further comprises: a second delay unit to delay the third clock signal by a period so that the third clock signal is synchronized with the eighth signal.

As a result, an output signal having a uniform pulse width and synchronous with the third clock signal can be produced.

According to a second aspect of the invention, a coding apparatus comprises: a first switching unit to switch a ninth signal and a tenth signal so as to output the first signal having data of the ninth and tenth signals and a bit rate twice as high as the ninth and tenth signals, the ninth and tenth signals respectively comprising one of two data produced by splitting a data of the first signal parallely and alternately into two; and a second switching unit to switch an eleventh signal and a twelfth signal so as to output the second signal having data of the eleventh and twelfth signals and a bit rate twice as high as the eleventh and twelfth signals, the eleventh and twelfth signals respectively comprising one of two data produced by splitting a data of the second signal parallely and alternately into two.

As a result, in the coding apparatus for the optical communication system, the low-speed ninth, tenth, 11th and 12th signals are coded and a high-speed eighth signal can be output. Thus, the signal preceding at high bit rate can be stably conducted.

### BRIEF DESCRIPTION OF THE DRAWINGS

The present invention will become more fully understood from the detailed description given hereinbelow and the appended drawings which given by way of illustration only, and thus are not intended as a definition of the limits of the present invention, and wherein;

FIG. 1 is a diagram showing a coding apparatus 100 including a cording circuit 3 according to an embodiment of the invention;

FIG. 2 is a diagram showing the coding circuit 3;

FIG. 3 is a timing chart for the operation of the coding circuit 3;

FIG. 4 is a diagram showing the phase space of the light;

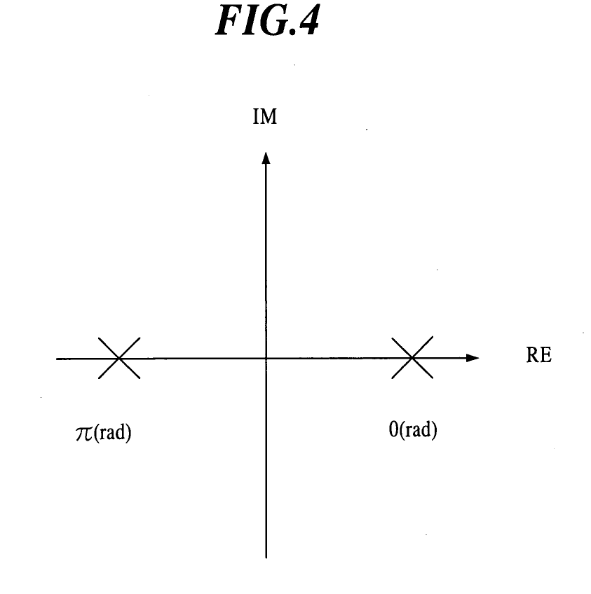

FIG. 5 is a diagram showing the phase modulation by the LN modulator 19;

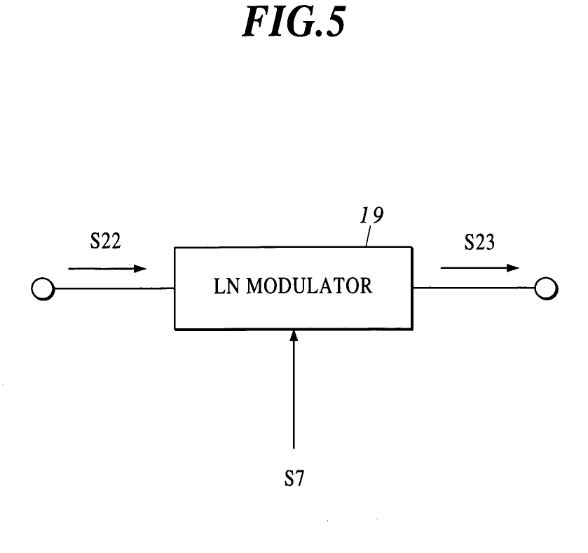

FIG. 6 is a diagram showing the conventional coding circuit 22;

FIG. 7 is a timing chart for the operation of the conventional coding circuit 22; and

FIG. 8 is a diagram showing the coding apparatus 200 including the conventional coding circuit 22.

### DETAILED DESCRIPTION OF PREFERRED EMBODIMENTS

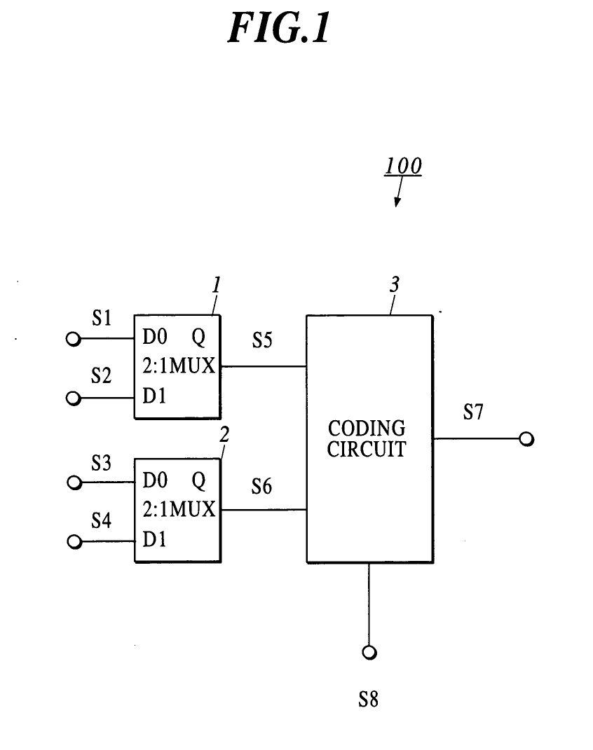

An embodiment of the invention is explained below with reference to FIGS. 1 to 3. FIG. 1 shows a configuration of the coding apparatus 100 including the coding circuit 3 according to the embodiment. In the description that follows, like in the prior art, the bit rate after coding is assumed to be 40 Gb/s. Also, the component parts different from those of the prior art are mainly explained.

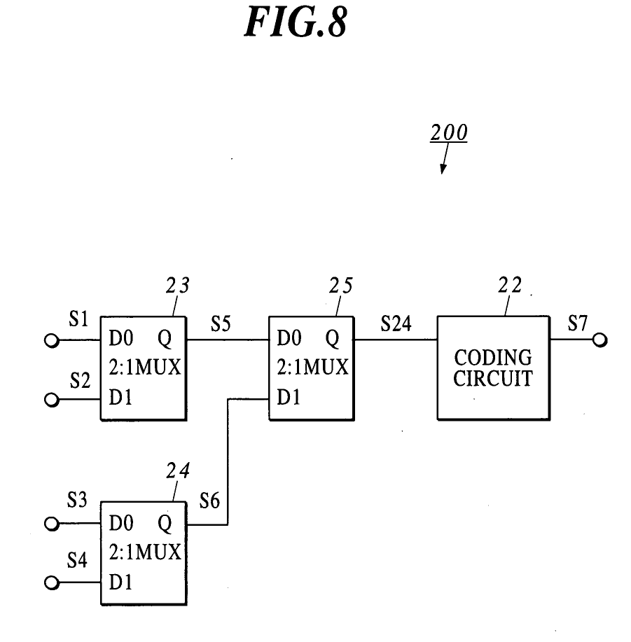

The coding apparatus 100 shown in FIG. 1 comprises a 2-to-1 multiplexer 1 as a first switching means, a 2-to-1 multiplexer 2 as a second switching means and the coding circuit 3 according to this embodiment. In the configuration shown in FIG. 1, an input signal S1 as a ninth signal, an input signal S2 as a tenth signal, an input signal S3 as an 11th signal and an input signal S4 as a 12th signal are input to the 2-to-1 multiplexers 1, 2, wherefrom signals S5, S6 are output in the same manner as in FIG. 8. The output signals S5, S6 are input to the coding circuit 3, and a control signal S7 is obtained from the output of the coding circuit 3. Also, a clock signal S8 is input to the coding circuit 3.

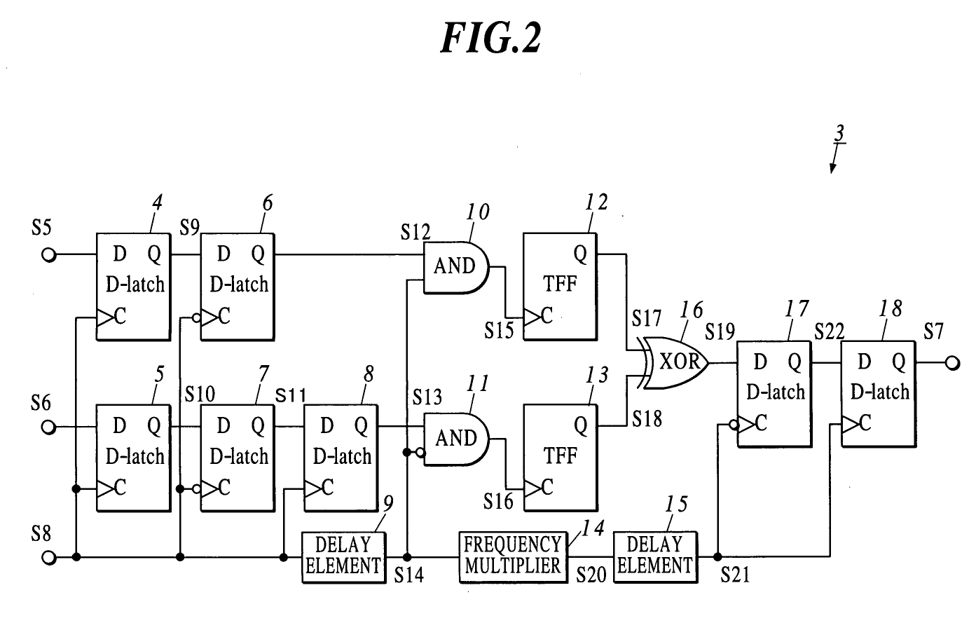

FIG. 2 shows a configuration of the coding circuit according to the embodiment shown in FIG. 1. The coding circuit 3 includes a D-latch circuit 4, a D-latch circuit 5, a D-latch circuit 6, a D-latch circuit 7, a D-latch circuit 8 as a data delay means, a delay element 9 as a first delay means, an AND circuit 10 as a first arithmetic means, an AND circuit 11 as a second arithmetic means, a T flip-flop 12 as a first holding signal inverting means, a T flip-flop 13 as a second holding signal inverting means, a frequency multiplexer 14 as a frequency multiplication means, a delay element 15 as a second delay means, an XOR circuit 16 as a third arithmetic means, a D latch circuit 17 and a D latch circuit 18.

In the D latch circuits 4, 5, 6, 7, 17, 18, each data of the signal input thereto is synchronized with the clock signal. The data terminals D of the D latch circuits 4, 5, 6, 7, 17, 18 are supplied with an input signal S5 as a first signal, an input signal S6 as a second signal, an output signal S9, an output signal S10, an output signal S19 and an output signal S22, respectively. Also, the clock terminals C of the D latch circuits 4, 5 are supplied with a clock signal S8 as a first clock signal, the clock terminals C of the D latch circuits 6, 7 with the inverted version of the clock signal S8, the clock terminal C of the D latch circuit 17 with the the inverted version of a clock signal S21 as a third clock signal, and the clock terminal C of the D latch circuit 18 with the clock signal S21.

In the D latch circuit 8, the period of the data in the output signal S13 as the third signal is delayed by one half period behind the period of the data in the output signal S12.

The XOR circuit 16 is a circuit for calculating the exclusive OR. The delay elements 9, 15 are the elements for delay the signal temporally, and are configured of a delay line, for example. The delay period of the delay element 9 corresponds to the delay period of the D latch circuits 6, 8, and the delay period of the delay element 15 to those of the AND circuits 10, 11, the T flip-flops 12, 13 and the XOR circuit 16. The frequency multiplier 14 has the function of doubling the frequency of the clock signal S14. The other component elements have a similar configuration to the prior art.

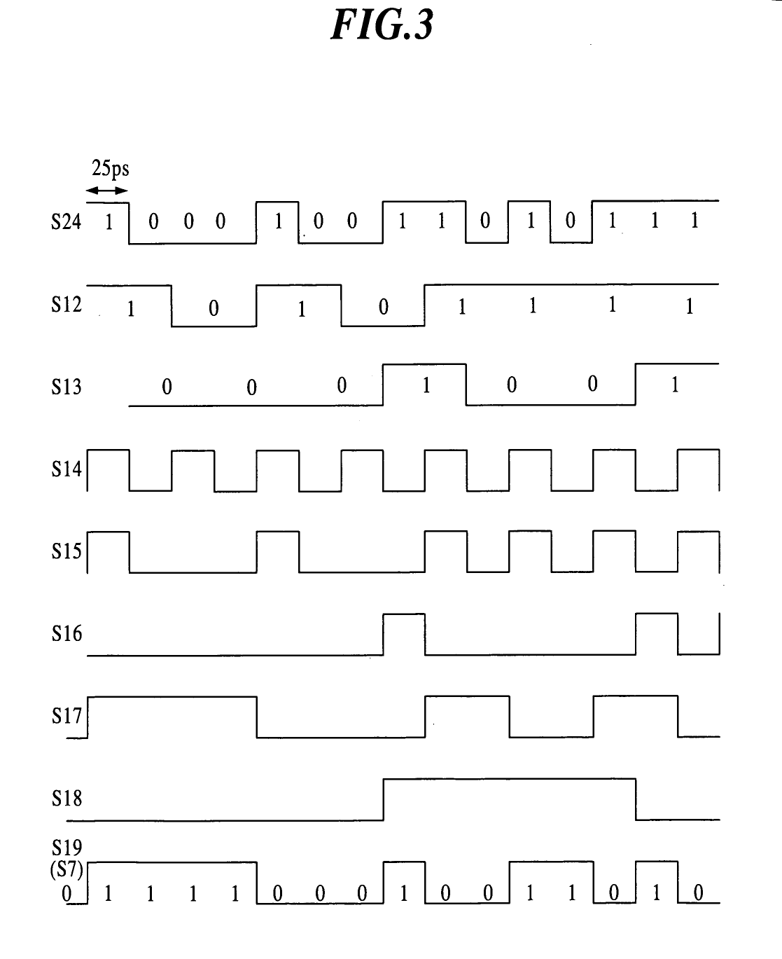

The operation of the coding circuit 3 according to the invention shown in FIG. 2 is explained with reference to FIGS. 2 and 3. In FIG. 2, the input signal S5 and the clock signal S8 are input to the D latch circuit 4, and the input signal S6 and the clock signal S8 to the D latch circuit 5. Further, the output signal S9 and the inverted version of the clock signal S8 from the D latch circuit 4 are input to the D latch circuit 6 thereby to produce the output signal S12. In similar fashion, the output signal S10 and the inverted version of the clock signal S8 output from the D latch circuit 5 are input to the D latch circuit 7 thereby to produce the output signal S11.

The D latch circuits 4, 6 as synchronizing means are equivalent to the D-FF (D flip-flop) circuit. In similar manner, the D latch circuits 5, 7 are equivalent to the D flip-flop circuit. The data constituting the input signals S5, S6 are sequentially latched by the clock signal S8 in the D latch circuits 4, 5, 6, 7. In other words, each data making up the input signals S5, S6 are synchronized with the clock signal S8 by the D latch circuits 4, 5, 6, 7.

The D latch circuit 8 is supplied with the output signal S11 of the D latch circuit 7 and the clock signal S8. The data period of the output signal S13 of the D latch circuit 8 is delayed by one half period (25 ps) behind the data period of the output signal S12.

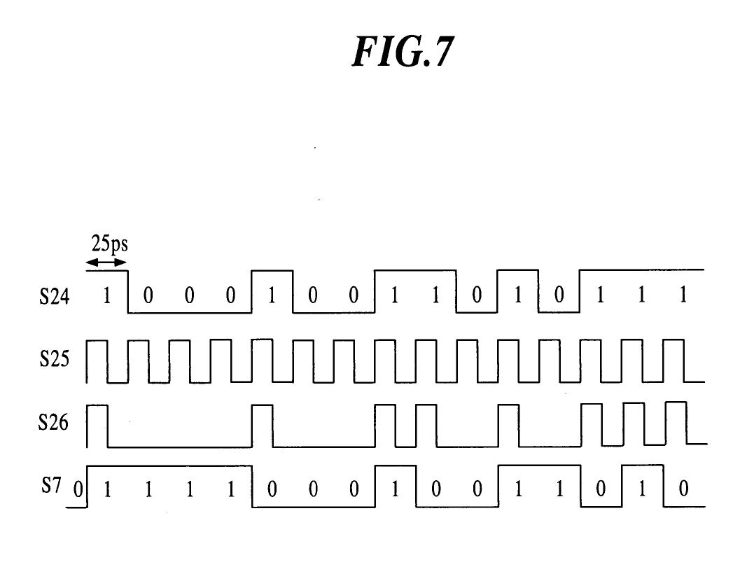

Now, the timing chart for the coding circuit 3 shown in FIG. 3 is explained. In FIG. 3, S24 designates the same signal as S24 in FIG. 7. Reference numerals S12, S13 designate the output signals S12, S13 shown in FIG. 2. As described above, the output signals S12, S13 of 20 Gb/s are as shown in FIG. 3 assuming that the the signal of 40 Gb/s constituting the transmission data is the same as the signal S24 in FIG. 7. In other words, the bit data of the signal S24 are distributed alternately to the signals S12 and S13, so that the signal S13 constitutes the data delayed by one half period (25 ps) behind the signal S12.

The AND circuit 10 shown in FIG. 2 is supplied with the output signal S12 and the clock signal S14 as a second clock signal delayed by the delay element 9 and conducts the logic product calculation. In similar fashion, the AND circuit 11 is supplied with the output signal S13 and the inverted version of the clock signal S14 delayed by the delay element 15 and conducts the logic product calculation. As the result of operation of the AND circuits 10, 11, the output signal S15 is produced as a fourth signal and the output signal S16 as a fifth signal.

In FIG. 3, reference numerals S12, S13, S14 designate the output signals S12, S13 and the clock signal S14, respectively, shown in FIG. 2. The result of the logic product of S12, S14 and S13, S14 shown in FIG. 3 are the signals S15 and S16, respectively. Reference numerals S15 and S16 designate the output signals S15 and S16 constituting the result of operation in the AND circuit shown in FIG. 3.

The output signal S15 of the AND circuit 10 is input to the T flip-flop 12 shown in FIG. 2, and the output signal S17 is output as a sixth signal. In similar fashion, the output signal S16 of the AND circuit 11 is input to the T flip-flop 13, and the output signal S18 is output as a seventh signal.

In FIG. 3, S17, S18 designate the output signals S17, S18, respectively, shown in FIG. 2. In FIG. 3, S17, S18 represent the result of the edge-up toggle operation of the T flip-flops 12, 13 shown in FIG. 2. In this case, the initial state of the signals S17, S18 is assumed to be 0.

The XOR circuit 16 shown in FIG. 2 is supplied with the output signals S17, S18 of the T flip-flops 12, 13, and the output signal S19 is output as an eighth signal.

In FIG. 3, S19 designates the output signal S19 shown in FIG. 7. In FIG. 3, S19 indicates the result of the exclusive OR operation of the output signals S17, S18 by the XOR circuit 16 shown in FIG. 2.

The D latch circuits 17, 18 shown in FIG. 2 operate at a speed twice as high as the D latch circuits 4, 5, 6, 7, 8. The clock signal S14, therefore, is changed to the clock signal S20 by the frequency multiplier 14. The clock signal S20 has a frequency twice as high as the clock signal S14. After that, the clock signal S20 is changed to the clock signal S21 through the delay element 15.

The D latch circuit 17 is supplied with the output signal S19 of the XOR circuit 16 and the inverted version of the clock signal S21. In similar manner, the D latch circuit 18 is supplied with the output signal S22 of the D latch circuit 17 and the clock signal S21. The control signal S7 is output from the D latch circuit 18. In this case, the D latch circuits 17, 18 are equivalent to the D flip-flop circuit as a pulse width adjusting means. The D latch circuits 17, 18 adjust the pulse width of the control signal S7 to the pulse width of the clock signal S21.

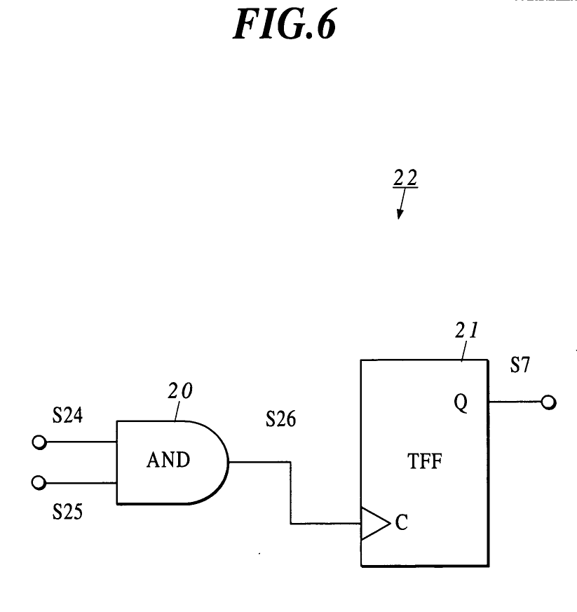

In FIG. 3, S7 designates the control signal S7 output from the D latch circuit 18. In FIG. 3, the signal S7 is the same logic result as the signal S19. Also, the signals S7 and S19 have the same value as the signal S7 shown in FIG. 6. The output signal S7 of the coding circuit 3 according to this invention, therefore, produces the same conversion result as the output signal S7 of the conventional coding circuit 22.

In the case where the initial state of both the T flip-flops 12, 13 is 1, the signals S19, S7 produce the same result as described above. In the case where the initial state of the T flip-flops 12, 13 are 1 and 0 or 0 and 1, on the other hand, the outputs 1 and 0 are inverted. Nevertheless, the DPSK modulation rule remains unchanged.

As described above, according to this embodiment, the coding circuit 3 so operates that the processable input signals S5, S6 of 20 Gb/s are coded and the high-speed signal S8 of 40 Gb/s can be output, thereby making possible stable preceding of high bit rate.

Also, the circuit operation with the input signals S5, S6 in synchronism with each other is made possible by the D latch circuits 4, 5, 6, 7 and the delay element 9.

Further, the control signal S7 having a. uniform pulse width and synchronized with the clock signal S21 can be produced by the D latch circuits 17, 18, the frequency multiplier 14 and the delay element 15.

Also, the coding apparatus 100 codes the low-speed input signals S1, S2, S3, S4 of 10 Gb/s and can output the high-speed signal S8 of 40 Gb/s. Thus, the stable precoding of the signal having a high bit rate is made possible.

Furthermore, the delay elements 9, 15 according to the aforementioned embodiment can be implemented also by the delay through the gate of an active element, for example.

In addition, the coding circuit according to the embodiment described above can be used as a part of the duobinary conversion scheme constituting one of the transmission coding techniques as well as the DPSK communication scheme.

The entire disclosure of Japanese Patent Application No. 2005-286987 filed on Sep. 30, 2005, including description, claims, drawings and summary are incorporated herein by reference in its entirety.

What is claimed is:

1. A coding circuit comprising:
a data delay unit to delay a period of a second signal by one half bit so as to output a third signal, the second signal comprising one of two data produced by splitting a data for cording parallely and alternately, a first signal comprising the other of the two data;
a first arithmetic unit to calculate a logic product of the first signal and a first clock signal having the same frequency as bit rate of the first signal so as to output a fourth signal;
a second arithmetic unit to calculate the logic product of the third signal and an inverted signal of the first clock signal so as to output a fifth signal;
a first holding signal inversion unit to invert the logic value of a data to be output so as to output a sixth signal every time a rising edge of the fourth signal is detected;
a second holding signal inversion unit to invert the logic value of a data to be output so as to output a seventh signal every time the rising edge of the fifth signal is detected; and
an exclusive OR operation unit to calculate an exclusive OR of the sixth signal and the seventh signal so as to output an eighth signal.

2. A coding circuit according to claim 1, further comprising: a first synchronizing unit to synchronize the first signal with the second signal by synchronization with an input of the first clock signal.

3. A coding circuit according to claim 1, further comprising: a first delay unit to delay the first clock signal by a predetermined period so as to output a second clock signal having the same frequency as the first clock signal,
wherein the first arithmetic unit calculates a logic product of the first signal and the second clock signal, and the second arithmetic unit calculates a logic product of the third signal and an inverted signal of the second clock signal.

4. A coding circuit according to claim 3, further comprising:
a frequency multiplication unit to output a third clock signal having a frequency twice as high as the second clock signal; and
a pulse width adjusting unit to adjust a pulse width of the eighth signal by synchronizing the eighth signal with the third clock signal.

5. A coding circuit according to claim 4, further comprising: a second delay unit to delay the third clock signal by a period for syncronization with the eighth signal.

6. A coding apparatus comprising:
a first switching unit to switch a ninth signal and a tenth signal so as to output the first signal having data of the ninth and tenth signals and a bit rate twice as high as the ninth and tenth signals, the ninth and tenth signals respectively comprising one of two data produced by splitting a data of the first signal parallely and alternately into two; and
a second switching unit to switch an eleventh signal and a twelfth signal so as to output the second signal having data of the eleventh and twelfth signals and a bit rate twice as high as the eleventh and twelfth signals, the eleventh and twelfth signals respectively comprising one of two data produced by splitting a data of the second signal parallely and alternately into two.
